(19) United States
(12) Patent Application Publication
(10) Pub. No.: US 2022/0391032 A1
(43) Pub. Date: Dec. 8, 2022

(54) POSITION DETECTING SENSOR AND MANUFACTURING METHOD FOR POSITION DETECTING SENSOR

(71) Applicant: Wacom Co., Ltd., Saitama (JP)

(72) Inventor: Yoshiharu MATSUMOTO, Saitama (JP)

(21) Appl. No.: 17/890,740

(22) Filed: Aug. 18, 2022

Related U.S. Application Data
(63) Continuation of application No. PCT/JP2021/000434, filed on Jan. 8, 2021.

(30) Foreign Application Priority Data
Mar. 12, 2020 (JP) 2020-042749

(51) Int. Cl. G06F 3/046; G06F 3/041; H05K 1/16

(52) U.S. Cl. CPC G06F 3/046; G06F 3/04186; H05K 1/16

(57) ABSTRACT

Provided is a position detecting sensor formed by adhering, to one surface of a substrate, by an adhesive, a sensor pattern section having electrode conductors each formed in a predetermined conductor pattern and made of a wire formed by insulatively coating a conductor. The sensor pattern section includes a first loop coil group including loop coils arranged in a first direction at predetermined intervals, the loop coils including the wire wound a predetermined number of times, and a second loop coil group including loop coils arranged at predetermined intervals in a second direction orthogonal to the first direction. Each group of at least one loop coil of the first loop coil group and each group of at least one of loop coil of the second loop coil group are arranged in an alternately superposed manner, and are adhered to the substrate by the adhesive.

### BACKGROUND

### Technical Field

The present disclosure relates to an electromagnetic induction type position detecting sensor and a manufacturing method for the position detecting sensor.

### Background Art

An electromagnetic induction type position detecting sensor is formed by a plurality of loop coils being arranged in an X-axis direction and a Y-axis direction at predetermined intervals on a substrate formed of an insulating material. In the existing technology, a wire wiring method and an etching method are known as methods of forming the loop coils onto the substrate.

In the wire wiring method of these methods, as described in PCT Patent Publication No. WO2016/194543, for example, patterns of X-axis direction loop coils and Y-axis direction loop coils are wired by using a pin table on which a plurality of wiring pins arranged in the X-axis direction and the Y-axis direction are upright, and sequentially hitching a wire formed by an insulation-coated conductor between wiring pins and folding back the wire. A sensor pattern section including an X-axis direction loop coil group formed by the plurality of X-axis direction loop coils and a Y-axis direction loop coil group formed by the plurality of Y-axis direction loop coils is thereby formed as an orthogonal wiring network. The X-axis direction loop coils and the Y-axis direction loop coils are formed as rectangular loop coils having long sides in the Y-axis direction and the X-axis direction.

In this case, the sensor pattern section as the orthogonal wiring network using the pin table is formed by forming an adhesive layer made of a double-sided tape, for example, on the pin table, and thereafter, in the existing technology, wiring all of the loop coils of one of the X-axis direction loop coil group and the Y-axis direction loop coil group and then wiring all of the loop coils of the other group. Then, a substrate formed of an insulating material is adhered onto the formed sensor pattern section via an adhesive (for example, a double-sided tape) and is extracted from the pin table, and thereafter a protective sheet is adhered onto the sensor pattern section via an adhesive, so that a position detecting sensor is produced.

This wire wiring method has the following advantages, for example.
The wire wiring method is suitable for large-sized position detecting sensors because of low manufacturing cost.
There is a high degree of freedom in sensor shape.
Because a wire formed by an insulation-coated conductor is used, the wire can be routed while straddling wires, and therefore, a small-pitch sensor pattern section in which loop coil overlaps are tolerated can be formed.
In a case where lead wires (hereinafter referred to as feeders) to be connected to one end and another end of a loop coil are disposed on the periphery of the substrate, an ineffective area can be reduced because the wire can be routed while straddling wires and there is no need to provide a space for insulation between the wires.

However, it has been found that the wire wiring method of the existing technology has a problem in that wiring distortion concentrates in a loop coil group that is wired subsequently within an X-axis direction loop coil group or a Y-axis direction loop coil group constituting the sensor pattern section in the formed position detecting sensor, and therefore, position detection accuracy of the position detecting sensor is degraded. Then, it has been found that the degradation in the position detection accuracy occurs more noticeably in a case where the loop coils are arranged at a small pitch and a high density in order to be able to perform position detection with high accuracy.

Reasons for the occurrence of this problem will be examined in the following.

The loop coils are hitched around wiring pins and are bent in a state in which tension is applied to the wires on the pin table. The loop coils are thus formed as rectangular loop coils. In this case, respective long sides of, for example, the rectangular shapes of the Y-axis direction loop coils and the X-axis direction loop coils have relatively long lengths respectively extending from one end to another end in the X-axis direction of a rectangular sensor region (position detection region) of the position detecting sensor and from one end to another end in the Y-axis direction of the rectangular sensor region.

Here, in a case of, for example, wiring all the loop coils of the Y-axis direction loop coil group after wiring all the loop coils of the X-axis direction loop coil group, even though a part of the X-axis direction loop coils that are wired first overlaps other X-axis direction loop coils, at least most of long side parts of the X-axis direction loop coils are directly adhered onto an adhesive on the pin table, and are thus securely fixed by the adhesive, including a central portion of the sensor region.

On the other hand, because the Y-axis direction loop coils wired subsequently are arranged on the already formed X-axis direction loop coil group, long side parts of the Y-axis direction loop coils intersect and overlap a plurality of wires of the X-axis direction loop coil group already present on the sensor region, and there are a large number of parts not fixed by the adhesive on the central portion of the rectangular sensor region of the position detecting sensor. Therefore, fixation strength of adhesion of the long side parts of the Y-axis direction loop coils wired subsequently by the adhesive is weakened.

As the position detection accuracy of the position detecting sensor is increased by the loop coils being arranged at a smaller pitch and a higher density, there are more parts in the Y-axis direction loop coils which parts intersect and overlap a plurality of wires of the X-axis direction loop coil group and are thus not fixed by the adhesive. Hence, as the accuracy of the position detecting sensor is increased, the fixation strength of adhesion of the long side parts of the Y-axis direction loop coils wired subsequently by the adhesive is weakened.

The long side parts of the Y-axis direction loop coils which parts are located on the central portion of the sensor region are parts located between wiring pins, and are parts that readily cause positional displacement in a case where the fixation strength is weak even when the wires are hitched around the wiring pins and are set in a state in which tension is applied to the wires.

Therefore, in a case of adhering a substrate via an adhesive onto the Y-axis direction loop coils of the sensor pattern section produced by forming the X-axis direction loop coil group and forming the Y-axis direction loop coil group on the X-axis direction loop coil group, wiring distortion by which the positions of the long side parts of the Y-axis direction loop coils with the weak fixation strength of the adhesion are displaced from original wiring positions occurs. The position detection accuracy of the position detecting sensor is consequently degraded.

As is clear from the foregoing description, the higher the accuracy of the position detecting sensor is, the larger the wiring distortion of the sensor pattern section is. There is thus a fear of being unable to obtain a position detecting sensor of high accuracy.

### BRIEF SUMMARY

It is an object of the present disclosure to provide a position detecting sensor that can solve the above problems.

In order to solve the above problems, there is provided a position detecting sensor formed by adhering a sensor pattern section to one surface of a substrate by an adhesive, the sensor pattern section having a plurality of electrode conductors each formed in a predetermined conductor pattern, the plurality of electrode conductors being made of a wire formed by insulatively coating a conductor. The sensor pattern section includes a first loop coil group formed by a plurality of loop coils being arranged in a first direction at predetermined intervals, the loop coils being formed by the wire being wound a predetermined number of times, and a second loop coil group formed by a plurality of loop coils being arranged at predetermined intervals in a second direction orthogonal to the first direction. Each one to plurality of loop coils of the first loop coil group and each one to plurality of loop coils of the second loop coil group are arranged in an alternately superposed manner, and are adhered to the substrate by the adhesive.

In the position detecting sensor of the above-described configuration, each one to plurality of loop coils of the first loop coil group and each one to plurality of loop coils of the second loop coil group are arranged in an alternately superposed manner, and are adhered to the substrate by the adhesive.

Hence, the loop coils of the first loop coil group and the loop coils of the second loop coil group are arranged while stably and uniformly being bonded to each other by the adhesive. Thus, according to the position detecting sensor of the above-described configuration, it is possible not only to avoid concentration of wiring distortion in either the first loop coil group or the second loop coil group but also to form the first loop coil group and the second loop coil group stably in a state with little distortion.

### BRIEF DESCRIPTION OF THE SEVERAL VIEWS OF THE DRAWINGS

FIGS. 1A and 1B are diagrams of assistance in explaining an example of a configuration of an embodiment of a position detecting sensor according to the present disclosure;

FIGS. 2A, 2B, 2C, and 2D are diagrams of assistance in explaining an example of a configuration of parts of a position detecting sensor according to an embodiment the present disclosure;

FIG. 3 is a diagram of assistance in explaining an example of a configuration of a position detecting circuit connected to a position detecting sensor according to the present disclosure;

FIG. 4 is a diagram of assistance in explaining an example of a manufacturing device for manufacturing a position detecting sensor according to an embodiment the present disclosure;

FIG. 5 is a diagram used to describe a manufacturing method for a position detecting sensor according an embodiment of to the present disclosure;

FIG. 6 is a diagram illustrating a flowchart of assistance in explaining a flow of a manufacturing method for a position detecting sensor according an embodiment of to the present disclosure;

FIG. 7 is a diagram used to describe a manufacturing method for a position detecting sensor according an embodiment of to the present disclosure;

FIG. 8 is a diagram used to describe a manufacturing method for a position detecting sensor according to a first embodiment of the present disclosure; and

FIGS. 9A, 9B, 9C, and 9D are diagrams of assistance in explaining another configuration example of parts of a position detecting sensor according to an embodiment of the present disclosure.

### DETAILED DESCRIPTION

An embodiment of a position detecting sensor according to the present disclosure and an embodiment of a manufacturing method therefor will hereinafter be described with reference to the drawings.

### [Embodiment of Position Detecting Sensor]

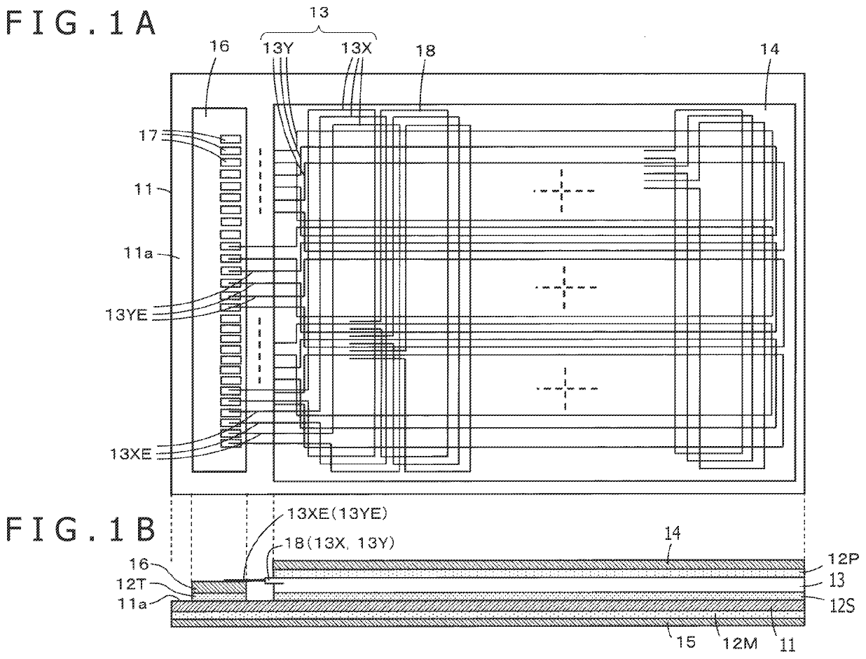

FIGS. 1A and 1B are diagrams of assistance in explaining a configuration of a position detecting sensor 1 according to a present embodiment. FIG. 1A is a diagram of a surface on which a sensor pattern section of the position detecting sensor 1 is formed as viewed from a direction orthogonal to the surface. FIG. 1B is a conceptual diagram of a configuration of a cross-section of the position detecting sensor 1. In the position detecting sensor 1 according to the present embodiment, as illustrated in FIGS. 1A and 1B, a sensor pattern section 13 including a plurality of loop coils as a plurality of electrode conductors are arranged in such a manner as to be adhered by an adhesive 12S onto one surface 11a of a rectangular sheet-shaped or film-shaped substrate (base plate) 11 formed of an insulation material, for example, polyethylene terephthalate (PET). A rectangular protective sheet 14 formed of an insulative material, for example, PET, is disposed in a state of being adhered by an adhesive 12P onto the sensor pattern section 13 in such a manner as to cover the whole of the sensor pattern section 13.

A metal sheet 15 as an example of an electromagnetic shield layer is adhered by an adhesive 12M onto the substrate 11 in such a manner as to cover the whole of a surface of the substrate 11 which surface is on a side opposite to the one surface 11a of the substrate 11. The metal sheet 15 in the present example is formed by aluminum and an amorphous sheet. The amorphous sheet of the metal sheet 15 plays a role of preventing an electromagnetic wave radiated from the sensor pattern section 13 from being emitted to the outside on the side opposite to the one surface 11a of the substrate 11, and an aluminum sheet of the metal sheet 15 plays a role of preventing noise from the outside on the side opposite to the one surface 11a of the substrate 11 from being mixed into the sensor pattern section 13. Incidentally, the metal sheet 15 may be adhered onto the substrate 11 in such a manner as to cover only a region of the surface of the substrate 11 which surface is on the side opposite to the one surface 11a of the substrate 11, the region being on the back side of the region of the sensor pattern section 13, instead of covering the whole of the surface of the substrate 11 which surface is on the side opposite to the one surface 11a of the substrate 11.

In addition, on the one surface 11a of the substrate 11, as illustrated in FIG. 1B, a terminal section 16 is adhered via an adhesive 12T in the region of an end edge portion not overlapping a region in which the sensor pattern section 13 is disposed. The terminal section 16 has a configuration in which terminal conductors 17 to be electrically connected to each of a plurality of electrode conductors of the sensor pattern section 13 are, for example, formed in a copper foil pattern by printing or the like on a sheet-shaped or film-shaped substrate formed by an insulation material, for example, PET. In the present embodiment, an upper portion of the terminal section 16 is not covered by the protective sheet 14.

As illustrated in FIG. 1A, the sensor pattern section 13 includes a plurality of loop coils as an example of a plurality of electrode conductors. In the present example, the plurality of loop coils include a plurality of X-axis direction loop coils 13X and a plurality of Y-axis direction loop coils 13Y.

The X-axis direction loop coils 13X are formed by rectangular loop coils having a vertical direction (for example, a Y-axis direction of position coordinates) of the substrate 11 as a long side direction. A plurality of the X-axis direction loop coils 13X are arranged side by side at predetermined intervals in a horizontal direction (for example, an X-axis direction of position coordinates) of the substrate 11. In addition, the Y-axis direction loop coils 13Y are formed by rectangular loop coils having the horizontal direction (X-axis direction of position coordinates) of the substrate 11 as a long side direction. The Y-axis direction loop coils 13Y are arranged side by side at predetermined intervals in the vertical direction (Y-axis direction of position coordinates) of the substrate 11.

Each of the plurality of X-axis direction loop coils 13X and the plurality of Y-axis direction loop coils 13Y constituting the sensor pattern section 13 is disposed on the one surface 11a of the substrate 11 while mutual overlaps of the plurality of X-axis direction loop coils 13X and the plurality of Y-axis direction loop coils 13Y are tolerated due to wires 18 formed by insulation-coated conductors in the present embodiment. In this case, as illustrated in FIG. 1A, each of the X-axis direction loop coils 13X and the Y-axis direction loop coils 13Y in the present embodiment is disposed in a predetermined pattern, or a rectangular loop coil pattern in the present example, at a predetermined position on the one surface 11a of the substrate 11.

In this case, in the present embodiment, the X-axis direction loop coils 13X in the present example are arranged in order in the X-axis direction from a left end edge side to a right end edge side in FIG. 1A of the rectangular substrate 11 while mutual overlaps of the X-axis direction loop coils 13X are tolerated. In addition, the Y-axis direction loop coils 13Y in the present example are arranged in order in the Y-axis direction from an upper end edge side to a lower end edge side in FIG. 1A of the rectangular substrate 11 while mutual overlaps of the Y-axis direction loop coils 13Y are tolerated. Needless to say, each of the X-axis direction loop coils 13X and each of the Y-axis direction loop coils 13Y may be arranged without overlaps.

In this case, in forming the sensor pattern section 13, the formation may be started with either an X-axis direction loop coil 13X or a Y-axis direction loop coil 13Y. In the following example, however, description will be made of a case where an X-axis direction loop coil 13X is formed first.

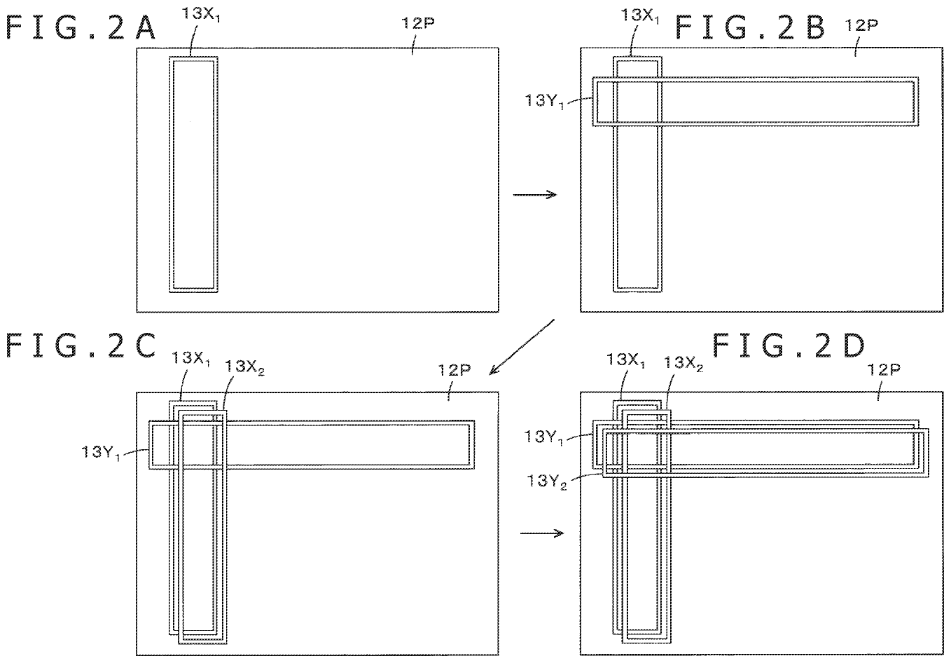

In the present embodiment, each one X-axis direction loop coil 13X and each one Y-axis direction loop coil 13Y are arranged in such a manner as to be formed alternately such that after one X-axis direction loop coil 13X is formed as illustrated in FIG. 2A, one Y-axis direction loop coil 13Y is formed as illustrated in FIG. 2B, next one X-axis direction loop coil 13X is subsequently formed as illustrated in FIG. 2C, further, one Y-axis direction loop coil 13Y is subsequently formed as illustrated in FIG. 2D, and so on.

At this time, respective opposite end portions 13XE and 13YE of the X-axis direction loop coils 13X and the Y-axis direction loop coils 13Y are set at predetermined positions on the one surface 11a of the substrate 11. As illustrated in FIG. 1A, the opposite end portions 13XE and 13YE are respectively positioned in such a manner as to be in a state of extending off the protective sheet 14 and being precisely located on corresponding terminal conductors 17 of the terminal section 16, the terminal conductors 17 being determined in advance as terminal conductors to which to connect the opposite end portions 13XE and 13YE. The respective opposite end portions 13XE and 13YE of the X-axis direction loop coils 13X and the Y-axis direction loop coils 13Y are in a state in which insulative coatings thereof are peeled off and the conductors are exposed. As illustrated in FIG. 1A, the exposed conductors are located on the terminal conductors 17 of the terminal section 16.

Then, though not illustrated, each of the terminal conductors 17 of the terminal section 16 is, for example, soldered and electrically connected to the respective opposite end portions 13XE and 13YE of the X-axis direction loop coils 13X and the Y-axis direction loop coils 13Y. For example, solder is mounted on each of the terminal conductors 17 of the terminal section 16 in advance. Each of the terminal conductors 17 of the terminal section 16 is soldered to the opposite end portions 13XE and 13YE of the X-axis direction loop coils 13X and the Y-axis direction loop coils 13Y by heating a solder part of each of the terminal conductors 17, of the terminal section 16, at which the respective opposite end portions 13XE and 13YE of the X-axis direction loop coils 13X and the Y-axis direction loop coils 13Y are located.

As described above, in the position detecting sensor 1 according to the present embodiment, the sensor pattern section 13 including the X-axis direction loop coils 13X and the Y-axis direction loop coils 13Y is formed by using the wires 18, and the sensor pattern section 13 is fixed to the substrate 11 by the adhesive 12S. Then, the protective sheet 14 is fixed to a side of the sensor pattern section 13, the side opposite to the substrate 11, by an adhesive 12P. Hence, the position detecting sensor 1 can be manufactured at low cost.

In the position detecting sensor 1 according to the foregoing embodiment, the terminal section 16 having the terminal conductors 17 formed in advance is formed on one surface 11a of the substrate 11. Then, conductor parts of the opposite end portions 13XE and 13YE of the X-axis direction loop coils 13X and the Y-axis direction loop coils 13Y arranged on a region of the substrate 11 which region does not overlap the terminal section 16 are exposed by peeling off coatings of the opposite end portions 13XE and 13YE of the X-axis direction loop coils 13X and the Y-axis direction loop coils 13Y. The exposed conductor parts of the opposite end portions 13XE and 13YE are positioned and arranged in such a manner as to be connectable to corresponding ones of the terminal conductors 17 of the terminal section 16.

Hence, the opposite end portions 13XE and 13YE formed by the respective exposed conductors of the X-axis direction loop coils 13X and the Y-axis direction loop coils 13Y of the sensor pattern section 13 can easily be electrically connected to the respective corresponding terminal conductors 17 of the terminal section 16 by soldering the opposite end portions 13XE and 13YE to the terminal conductors 17 of the terminal section 16.

As described above, the position detecting sensor 1 according to the foregoing embodiment has loop coils as electrode conductors formed by use of the wires 18 formed of insulation-coated conductors. Thus, a position detecting sensor of an inexpensive and simple configuration can be provided, and connection between the position detecting sensor 1 and an external circuit is made very easy by use of the terminal section 16.

In the sensor pattern section 13, each one X-axis direction loop coil 13X and each one Y-axis direction loop coil 13Y are arranged in such a manner as to be formed alternately. Thus, the X-axis direction loop coils 13X and the Y-axis direction loop coils 13Y are arranged while stably and uniformly being bonded to each other by an adhesive. Consequently, in the position detecting sensor 1, concentration of wiring distortion in either an X-axis direction loop coil group or a Y-axis direction loop coil group is avoided, and the X-axis direction loop coil group and the Y-axis direction loop coil group can be formed stably in a state with little distortion.

### [Position Detecting Circuit Using Position Detecting Sensor According to Embodiment]

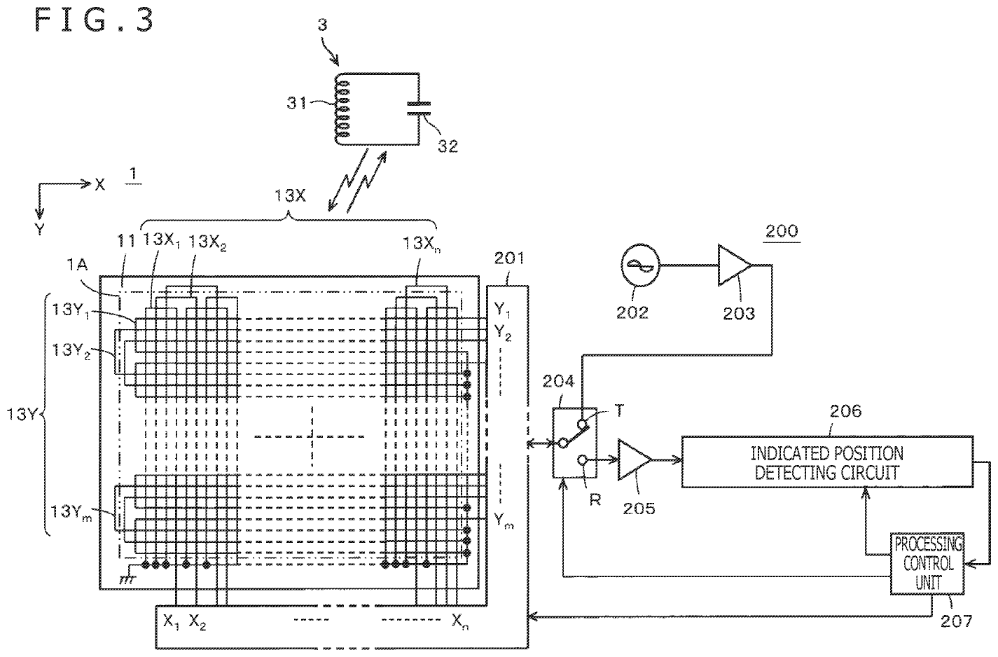

Next, with reference to FIG. 3, description will be made of an example of a configuration of a position detecting circuit 200 of an electromagnetic induction type that detects a position indicated by a pen type position indicator by using the position detecting sensor 1 according to the foregoing embodiment. Incidentally, as illustrated in FIG. 3, a pen type position indicator 3 used in conjunction with the position detecting sensor 1 according to the present embodiment includes a resonance circuit including a coil 31 and a capacitor 32 connected in parallel with the coil 31.

In this case, in the example of FIG. 3, the X-axis direction loop coils 13X are formed by n (n is an integer of 2 or more) rectangular loop coils 13X₁ to 13Xₙ arranged in the X-axis direction, and the Y-axis direction loop coils 13Y are formed by m (m is an integer of 2 or more) loop coils 13Y₁ to 13Yₘ arranged in the Y-axis direction. In the position detecting sensor 1, the plurality of X-axis direction loop coils 13X and the plurality of the Y-axis direction loop coils 13Y constitute a position detection area.

The position detecting sensor 1 is connected to a position detecting circuit 200 via the terminal section 16. In the example of FIG. 3, the position detecting circuit 200 includes a selecting circuit 201, an oscillator 202, a current driver 203, a transmission/reception switching circuit 204, a receiving amplifier 205, an indicated position detecting circuit 206, and a processing control unit 207.

The selecting circuit 201 sequentially selects one loop coil among the plurality of X-axis direction loop coils 13X and the plurality of Y-axis direction loop coils 13Y. The selecting circuit 201 makes the selected loop coil transmit a signal to the position indicator 3 and receive the signal fed back from the position indicator 3.

The transmission/reception switching circuit 204 switching-controlled by the processing control unit 207 is connected to the selecting circuit 201. When the transmission/reception switching circuit 204 is connected to a transmission side terminal T, an alternating-current signal is supplied from the oscillator 202 to the selecting circuit 201. When the transmission/reception switching circuit 204 is connected to a reception side terminal R, a signal from the selecting circuit 201 is supplied to the indicated position detecting circuit 206 through the receiving amplifier 205.

The indicated position detecting circuit 206 detects an induced voltage generated in the loop coil of the position detecting sensor 1, that is, a received signal, converts the detected output signal into a digital signal, and outputs the digital signal to the processing control unit 207. The processing control unit 207 calculates the coordinate value of an indicated position in the X-axis direction and the Y-axis direction of the position indicator 3 on the basis of the digital signal from the indicated position detecting circuit 206, that is, the level of a voltage value of the induced voltage generated in each loop coil.

### [Embodiment of Manufacturing Method for Position Detecting Sensor According to Embodiment]

Description will next be made of an embodiment of a manufacturing method for the position detecting sensor 1 having the configuration illustrated in FIGS. 1A and 1B.

### <Embodiment of Manufacturing Method for Position Detecting Sensor>

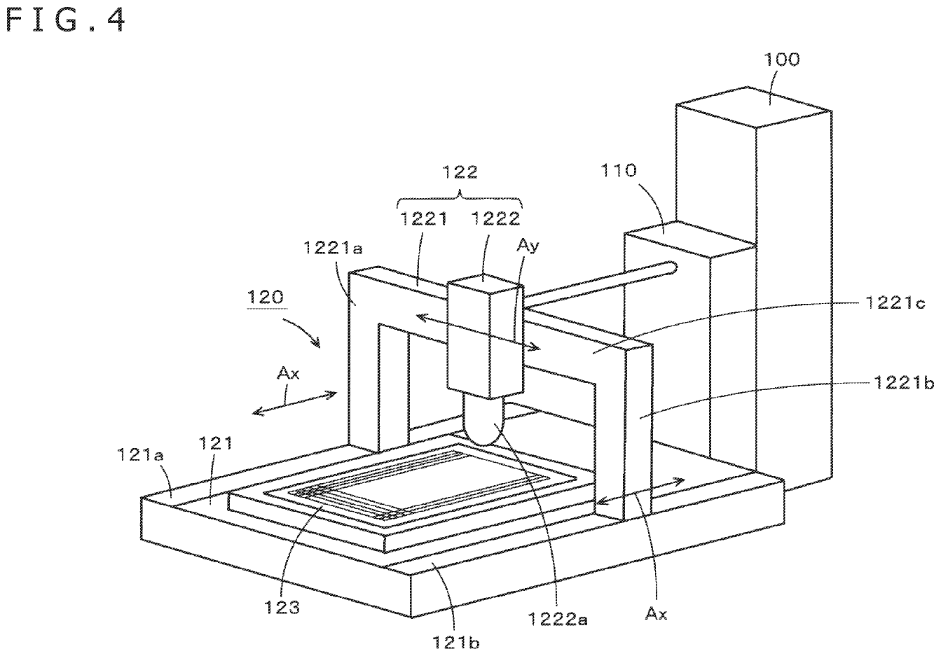

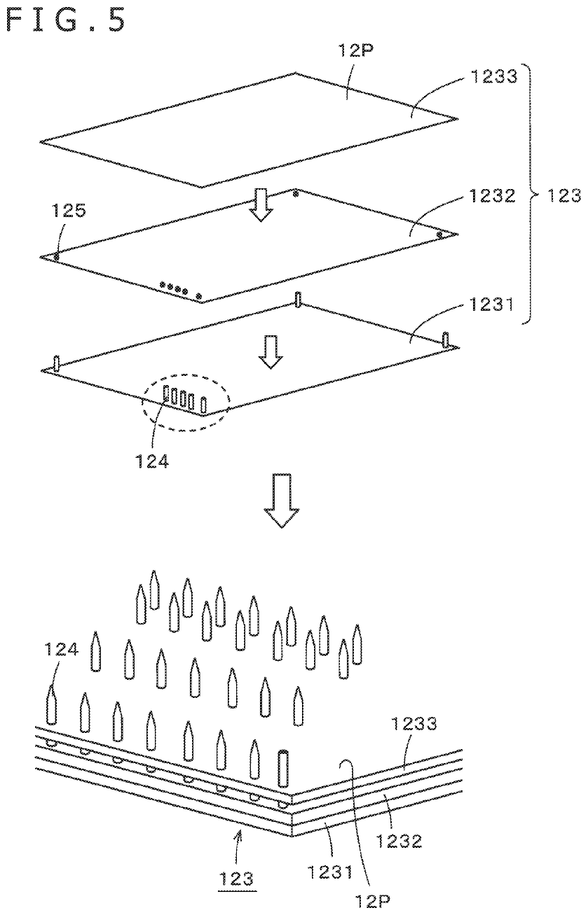

FIG. 4 and FIG. 5 are diagrams of assistance in explaining an embodiment of a manufacturing method for the position detecting sensor 1. FIG. 4 is a diagram illustrating an example of a configuration of a position detecting sensor manufacturing device that performs the manufacturing method according to the present embodiment. The position detecting sensor manufacturing device in the present example includes a wiring supply unit 100, a preprocessing unit 110, and a wiring unit 120.

The wiring unit 120 includes a work table 121 for forming the position detecting sensor 1 and a two-axis moving wiring device 122 provided on the work table 121. The two-axis moving wiring device 122 includes a moving bridge 1221 that slidingly moves in the X-axis direction of the position detecting sensor 1 (see the direction of arrows Ax in FIG. 4) and a wiring nozzle mechanism 1222 that slidingly moves in the Y-axis direction of the position detecting sensor 1 (see the direction of an arrow Ay in FIG. 4).

The moving bridge 1221 includes two leg portions 1221a and 1221b and a bridging portion 1221c that straddles and bridges the two leg portions 1221a and 1221b in a direction along the Y-axis direction of the position detecting sensor 1. The two leg portions 1221a and 1221b of the moving bridge 1221 are mounted on two respective rails 121a and 121b provided in the X-axis direction on the work table 121. The moving bridge 1221 slidingly moves in the X-axis direction while being guided by the two rails 121a and 121b, in a state in which the bridging portion 1221c maintains a state of being parallel with the Y-axis direction.

The wiring nozzle mechanism 1222 is attached to the bridging portion 1221c of the moving bridge 1221 in such a manner as to be movable in the bridging direction of the bridging portion 1221c (see the Y-axis direction of the position detecting sensor 1 (the direction of the arrow Ay in FIG. 4)). A wiring nozzle 1222a is attached to a portion of the wiring nozzle mechanism 1222 which portion is opposed to the surface of the work table 121. The wiring nozzle 1222a feeds a coated conductor preprocessed by the preprocessing unit 110 from an ejection port to the outside.

With the above configuration, the wiring nozzle 1222a can move in any direction on a two-dimensional plane of the work table 121 by the sliding movement in the X-axis direction of the moving bridge 1221 and the sliding movement in the Y-axis direction of the wiring nozzle mechanism 1222 in the two-axis moving wiring device 122.

The two-axis moving wiring device 122 includes a movement control unit not illustrated in FIG. 4. The two-axis moving wiring device 122 is configured such that the movement control unit controls the sliding movement in the X-axis direction of the moving bridge 1221 and the sliding movement in the Y-axis direction of the wiring nozzle mechanism 1222. In the present embodiment, the movement control unit stores, in advance, information regarding movement trajectories for moving the wiring nozzle 1222a in such a manner as to arrange each of the plurality of X-axis direction loop coils 13X and each of the plurality of Y-axis direction loop coils 13Y.

The movement control unit of the two-axis moving wiring device 122 controls the sliding movement in the X-axis direction of the moving bridge 1221 and the sliding movement in the Y-axis direction of the wiring nozzle mechanism 1222 on the basis of the information stored in the movement control unit. The movement control unit thereby performs movement control of the wiring nozzle 1222a in such a manner as to arrange each of the plurality of X-axis direction loop coils 13X and each of the plurality of Y-axis direction loop coils 13Y.

The work table 121 of the wiring unit 120 is provided with a pin table 123 on which guide pins 124 are arranged to guide the X-axis direction loop coils 13X and the Y-axis direction loop coils 13Y in such a manner as to form the X-axis direction loop coils 13X and the Y-axis direction loop coils 13Y as loop coil patterns by wires 18.

FIG. 5 is a diagram of assistance in explaining an example of a configuration of the pin table 123. As illustrated in an upper part of FIG. 5, the pin table 123 includes a guide pin attachment plate 1231, an intermediate plate 1232, and a peeling sheet 1233. The pin table 123 is formed by coupling the guide pin attachment plate 1231, the intermediate plate 1232, and the peeling sheet 1233 to each other as illustrated in a lower part of FIG. 5. Incidentally, a diagram of the pin table 123 in the lower part of FIG. 5 is an enlarged view of a region corresponding to a region illustrated enclosed by a dotted line in a diagram in the upper part of FIG. 5.

Attached to the guide pin attachment plate 1231 are a large number of guide pins 124 for guiding a wire 18 ejected from the wiring nozzle 1222a, in such a manner as to form each of the plurality of X-axis direction loop coils 13X and each of the plurality of Y-axis direction loop coils 13Y by the wire 18. In FIG. 5, for the purpose of description, illustrated are the guide pins 124 attached only to an end portion of the guide pin attachment plate 1231. However, in actuality, the guide pins 124 are at least provided at respective point positions at which each of the plurality of X-axis direction loop coils 13X and each of the plurality of Y-axis direction loop coils 13Y are bent.

The intermediate plate 1232 is provided between the guide pin attachment plate 1231 and the peeling sheet 1233. As illustrated in FIG. 5, the intermediate plate 1232 has through holes 125 formed at positions corresponding to the respective guide pins 124 provided to the guide pin attachment plate 1231.

The peeling sheet 1233 in the present example is formed by a double-sided tape. The peeling sheet 1233 is provided over the intermediate plate 1232 adhered to the guide pin attachment plate 1231, and thereafter release paper on an exposed side of peeling sheet 1233, the exposed side being opposite to an intermediate plate 1232 side, is removed, thereby forming the peeling sheet 1233. Hence, an adhesive (adhesive 12P in FIG. 1) is exposed on the exposed side of the peeling sheet 1233, the exposed side being opposite to the intermediate plate 1232 side. At this time, the guide pins 124 pierce the peeling sheet 1233, and distal ends of the guide pins 124 project on the peeling sheet 1233. Incidentally, the distal ends of the guide pins 124 in the present example are sharpened into a needle shape.

As described above, formed is the pin table 123 in which the guide pin attachment plate 1231, the intermediate plate 1232, and the peeling sheet 1233 are coupled to each other as illustrated in the lower part of FIG. 5 and a large number of guide pins 124 are planted at predetermined positions.

The coated conductor fed from the wiring nozzle 1222a of the wiring nozzle mechanism 1222 forms each of the plurality of X-axis direction loop coils 13X and the plurality of Y-axis direction loop coils 13Y as a predetermined loop coil pattern on the exposed adhesive 12P of the peeling sheet 1233 of the pin table 123. The sensor pattern section 13 is consequently formed. Incidentally, release paper remains affixed to the intermediate plate 1232 side of the peeling sheet 1233. Thus, the formed sensor pattern section 13 can easily be peeled off from the pin table 123.

The position detecting sensor 1 is manufactured by a procedure as described in the following, by using the position detecting sensor manufacturing device having the configuration as described above. Incidentally, the position detecting sensor manufacturing device of FIG. 4 performs the manufacture of the position detecting sensor 1 by performing sequence control of operation of each of the wiring supply unit 100, the preprocessing unit 110, and the wiring unit 120 by a sequence control unit not illustrated.

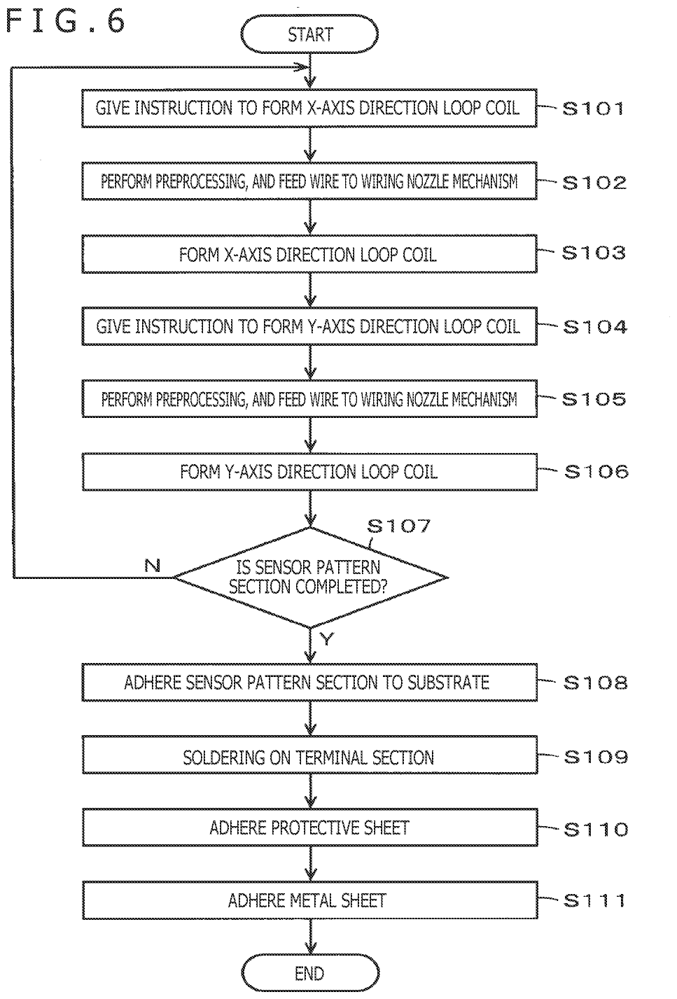

FIG. 6 is a flowchart of assistance in explaining a flow of steps of a first embodiment of the manufacturing method for the position detecting sensor 1 according to the present embodiment. The manufacturing method for the position detecting sensor 1 according to the present embodiment will be described with reference to FIG. 6. Incidentally, the processing of each in the following is performed by control of the sequence control unit of the position detecting sensor manufacturing device.

First, the sequence control unit gives an instruction to form an X-axis direction loop coil 13X to each of the wiring supply unit 100, the preprocessing unit 110, and the wiring unit 120, and makes the wiring supply unit 100 feed a wire 18 to the preprocessing unit 110 (S101). The preprocessing unit 110 supplied with the wire 18 performs preprocessing of cutting the wire 18 supplied from the wiring supply unit 100, to a length adjusted to the X-axis direction loop coil 13X, and exposing a conductor by peeling off coatings of opposite end portions of the wire 18. The preprocessing unit 110 feeds the wire 18 resulting from the preprocessing to the wiring nozzle mechanism 1222 of the wiring unit 120 (S102).

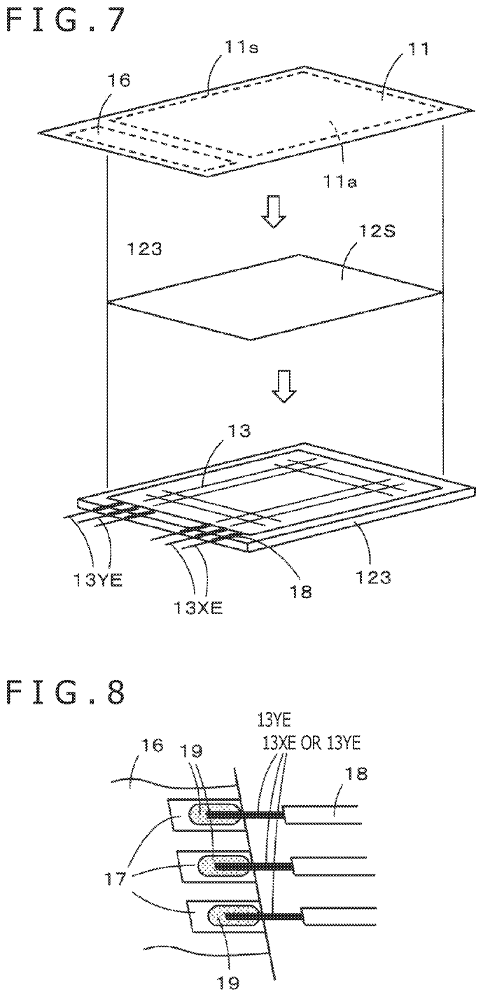

The wiring unit 120 forms the X-axis direction loop coil 13X on the pin table 123 while hitching the wire 18 to guide pins 124 by performing movement control of the wiring nozzle 1222a of the wiring nozzle mechanism 1222 by the movement control unit of the two-axis moving wiring device 122 (S103; see FIG. 2A). In this case, as illustrated in FIG. 7, opposite end portions 13XE, of the X-axis direction loop coil 13X, in which the conductor of the wire 18 is exposed project in the X-axis direction from the pin table 123. The opposite end portions 13XE are positioned in such a manner as to be located on the corresponding terminal conductors 17 of the terminal section 16, as illustrated in the foregoing description of FIG. 1, by the wire 18 being arranged while the guide pins 124 guide the wire 18.

After the formation of this one X-axis direction loop coil 13X is ended, the sequence control unit gives an instruction to form a Y-axis direction loop coil 13Y to each of the wiring supply unit 100, the preprocessing unit 110, and the wiring unit 120, and makes the wiring supply unit 100 feed the wire 18 fed to the preprocessing unit 110 (S104). The preprocessing unit 110 supplied with the wire 18 performs preprocessing of cutting the wire 18 supplied from the wiring supply unit 100, to a length adjusted to the Y-axis direction loop coil 13Y, and exposing a conductor by peeling off coatings of opposite end portions of the wire 18. The preprocessing unit 110 feeds the wire 18 resulting from the preprocessing to the wiring nozzle mechanism 1222 of the wiring unit 120 (S105).

The wiring unit 120 forms the Y-axis direction loop coil 13Y on the pin table 123 while hitching the wire 18 to guide pins 124 by performing movement control of the wiring nozzle 1222a of the wiring nozzle mechanism 1222 by the movement control unit of the two-axis moving wiring device 122 (S106; see FIG. 2B). In this case, as illustrated in FIG. 7, opposite end portions 13YE, of the Y-axis direction loop coil 13Y, in which the conductor of the wire 18 is exposed project in the Y-axis direction from the pin table 123. Then, the opposite end portions 13YE are positioned in such a manner as to be located on the corresponding terminal conductors 17 of the terminal section 16, as illustrated in the foregoing description of FIG. 1, by the wire 18 being arranged while the guide pins 124 guide the wire 18.

After the formation of the one X-axis direction loop coil 13X and the one Y-axis direction loop coil 13Y is ended, the sequence control unit ends formation of all of the X-axis direction loop coils 13X and the Y-axis direction loop coils 13Y on the pin table 123, and determines whether or not the sensor pattern section 13 is completed (S107).

When the sequence control unit determines at S107 that the sensor pattern section 13 is not completed, the sequence control unit returns the processing to S101, and performs control to repeat processing similar to that of S101 to S106 for each of one X-axis direction loop coil 13X and one Y-axis direction loop coil 13Y at next positions, as illustrated in FIGS. 2C and 2D. In the present example, the X-axis direction loop coil 13X and the Y-axis direction loop coil 13Y at the next positions are adjacent to the X-axis direction loop coil 13X and the Y-axis direction loop coil 13Y formed previously.

When it is determined at S107 that the sensor pattern section 13 is completed, the substrate 11 is positioned and pressed onto the sensor pattern section 13 on the pin table 123 via the adhesive 12S formed by peeling off release paper from a double-sided tape, for example, as illustrated in FIG. 7, in such a manner that the sensor pattern section 13 on the pin table 123 is adhered to the substrate 11 by the adhesive 12S (S108).

In this case, as illustrated in FIG. 7, the terminal section 16 having a plurality of terminal conductors 17 (omitted in FIG. 7; see FIG. 1) formed thereon is adhered and formed in advance on the surface 11a of the substrate 11, the surface 11a being opposed to the pin table 123. In the present embodiment, as illustrated in FIG. 1, the substrate 11 includes a region in which the terminal section 16 is formed and a region 11s of the sensor pattern section 13 (see regions indicated by dotted lines in FIG. 7).

In the present embodiment, the double-sided tape constituting the adhesive 12S is formed in a size corresponding to the size of the region 11s of the sensor pattern section 13, and the double-sided tape in the present example is positioned such that the adhesive 12S is not present on the region in which the terminal section 16 is formed. Then, the substrate 11 is positioned such that the sensor pattern section 13 of the pin table 123 corresponds to the region 11s of the sensor pattern section 13, and the substrate 11 is pressed onto the pin table 123 via the adhesive 12S.

The positioning of the double-sided tape as the adhesive 12S and the substrate 11 is performed by predetermined ones of the guide pins 124 (for example, ones corresponding to four corner positions of the region 11s) projecting on the pin table 123. Incidentally, the adhesive 12S may be adhered to the region 11s of the substrate 11 in advance.

On the other hand, as for the sensor pattern section 13 on the pin table 123, as illustrated in FIG. 7, opposite end portions 13XE and 13YE of each of the plurality of X-axis direction loop coils 13X or the plurality of Y-axis direction loop coils 13Y, the opposite end portions having a conductor exposed, are in a state of projecting in the direction of the terminal section 16 from the region 11s of the sensor pattern section 13 in such a manner as to be connected to the respective corresponding terminal conductors 17 of the terminal section 16.

When the one surface 11a side of the substrate 11 is pressed against the pin table 123 in the positioned state, as described above, the guide pins 124 penetrate and pierce the substrate 11, while the sensor pattern section 13 is adhered to the region 11s of the substrate 11 by the adhesive 12S. Then, as illustrated in FIG. 8, the respective opposite end portions 13XE and 13YE of the plurality of X-axis direction loop coils 13X or the plurality of Y-axis direction loop coils 13Y are located on the corresponding terminal conductors 17 of the terminal section 16.

After the sensor pattern section 13 is thus adhered to the one surface 11a of the substrate 11 by the adhesive 12S, the substrate 11 is peeled off from the pin table 123 at S108. In this case, a raising mechanism using an unillustrated robot hand or the like separates and raises the substrate 11 from the guide pin attachment plate 1231 together with the parts corresponding to the intermediate plate 1232 and the peeling sheet 1233, and thereby removes the substrate 11 from the guide pins 124. Incidentally, instead of raising the substrate 11 together with the parts corresponding to the intermediate plate 1232 and the peeling sheet 1233, the substrate 11 may be removed from the guide pins 124 by lowering the guide pin attachment plate 1231 downward by the height of the guide pins 124 or more in a state in which an unillustrated robot hand or the like holds the substrate 11 together with the parts corresponding to the intermediate plate 1232 and the peeling sheet 1233.

As described above, the sensor pattern section 13 is adhered to the one surface 11a of the substrate 11 removed from the pin table 123, and as described above, the respective opposite end portions 13XE and 13YE, of the plurality of X-axis direction loop coils 13X or the plurality of Y-axis direction loop coils 13Y, in which the conductor is exposed by peeling off the coating of the wire 18 are located on the corresponding terminal conductors 17 of the terminal section 16.

In the present embodiment, as illustrated in FIG. 8, solder 19 is mounted in advance on each terminal conductor 17 of the terminal section 16 on the one surface 11a of the substrate 11. The solder 19 is melted by heating the part corresponding to the solder 19 on each terminal conductor 17 of the terminal section 16. The opposite end portions 13XE and 13YE in which the conductor is exposed by peeling off the coating of the wire 18 are soldered and electrically connected to the corresponding terminal conductors 17 of the terminal section 16 (S109).

Thereafter, the adhesive 12P is exposed by peeling off release paper from the peeling sheet 1233 bonded on the sensor pattern section 13 adhered to the one surface 11a of the substrate 11 provided with the peeling sheet 1233, the substrate 11 having been removed from the guide pins 124. Then, the protective sheet 14 (see FIGS. 1A and 1B) is adhered by the adhesive 12P onto the sensor pattern section 13 over the one surface 11a of the substrate 11, and the protective sheet 14 covers the sensor pattern section 13 (S110).

Next, in the present embodiment, the metal sheet 15 constituting the electromagnetic shield layer is adhered to a surface of the substrate 11, the surface being on a side opposite to the one surface 11a by the adhesive 12M formed by a double-sided tape, for example (S111).

The position detecting sensor 1 can be manufactured as described above. Incidentally, when the position detecting sensor 1 is of a size having a redundant region for manufacturing in a case where the position detecting sensor 1 is produced in the above steps, the external shape of the position detecting sensor 1 is formed into a predetermined external shape by cutting the unnecessary part at the end.

Incidentally, the preprocessing unit 110 may perform only the processing of exposing the conductor by peeling off the coating of the wire 18, and the wiring nozzle mechanism 1222 of the wiring unit 120 may perform the processing of cutting the wire 18 to a length adjusted to each of the X-axis direction loop coils 13X or the Y-axis direction loop coils 13Y.

As described above, according to the manufacturing method for the position detecting sensor in accordance with the present embodiment, it is possible to manufacture the position detecting sensor 1 in which the sensor pattern section 13 is easily arranged on the one surface 11a of the substrate 11 by using the wire 18 formed by an insulation-coated conductor, and electric connection between the terminal conductors 17 of the terminal section 16 and the respective loop coils of the sensor pattern section 13 can be established easily. Then, mass production of the position detecting sensor 1 is also made possible by use of the manufacturing method according to the present embodiment.

On the pin table 123, the X-axis direction loop coils 13X and the Y-axis direction loop coils 13Y of the sensor pattern section 13 are formed alternately on a one-by-one basis, and are bonded to the adhesive 12P of the peeling sheet 1233. Thus, the X-axis direction loop coils 13X and the Y-axis direction loop coils 13Y are fixed to each other by the adhesive 12P stably and uniformly. Hence, a uniform fixed state of the X-axis direction loop coils 13X and the Y-axis direction loop coils 13Y is maintained also when the substrate 11 is adhered onto the sensor pattern section 13 by the adhesive 12S.

Consequently, in the position detecting sensor 1 according to the present embodiment, concentration of wiring distortion in either the X-axis direction loop coil group or the Y-axis direction loop coil group is avoided, and the X-axis direction loop coil group and the Y-axis direction loop coil group can be formed on the substrate 11 stably in a state with little wiring distortion.

Even when each of the X-axis direction loop coils 13X and the Y-axis direction loop coils 13Y is formed at a small pitch, the X-axis direction loop coil group and the Y-axis direction loop coil group can be formed stably in a state with little wiring distortion. Thus, higher precision of the position detecting sensor can easily be realized.

### <Other Embodiments of Manufacturing Method for Position Detecting Sensor>

The manufacturing method for the position detecting sensor according to the foregoing embodiment uses the pin table 123 on which the guide pins 124 are formed. However, the position detecting sensor 1 can be formed without the use of the pin table 123.

In another embodiment of the manufacturing method for the position detecting sensor, a layer of the adhesive 12S is provided on the one surface 11a of the substrate 11, and the terminal section 16 and the sensor pattern section 13 are arranged on the layer of the adhesive 12S by a wiring nozzle mechanism. The wiring nozzle mechanism of a wiring unit in that case forms a loop coil pattern by moving a wiring nozzle while pressing and adhering the wire 18 to the adhesive 12S side on the one surface 11a of the substrate 11 instead of forming the loop coil pattern in such a manner as to hitch the wire 18 to the guide pins 124. A well-known configuration can be used as a configuration for that purpose, and therefore, an example of a configuration thereof will be omitted here. Others are similar to those of the foregoing embodiment of the manufacturing method for the position detecting sensor.

Incidentally, description has been made in the foregoing other embodiment of the manufacturing method for the position detecting sensor in which, after the substrate 11 is coated thereon with the layer of the adhesive 12S, the coated conductor is adhered to the layer of the adhesive. However, a coated conductor provided with an adhesive that is melted by heat, for example, may be used as the coated conductor of the wire 18 instead of applying the layer of the adhesive 12S, and the wire 18 may be adhered onto the substrate 11 while the adhesive of the coated conductor is melted by heat.

### [Modification of Position Detecting Sensor According to Foregoing Embodiment]

In the position detecting sensor 1 according to the foregoing embodiment, the X-axis direction loop coils 13X and the Y-axis direction loop coils 13Y are formed alternately on a one-by-one basis. However, the X-axis direction loop coils 13X and the Y-axis direction loop coils 13Y may be configured in such a manner as to be formed alternately on a plurality-by-plurality basis. Also in this case, suppose that the X-axis direction loop coils 13X are arranged in order in the X-axis direction from the left end edge side to the right end edge side in FIG. 1A of the rectangular substrate 11 while mutual overlaps of the X-axis direction loop coils 13X are tolerated, and the Y-axis direction loop coils 13Y are arranged in order in the Y-axis direction from the upper end edge side to the lower end edge side in FIG. 1A of the rectangular substrate 11 while mutual overlaps of the Y-axis direction loop coils 13Y are tolerated.

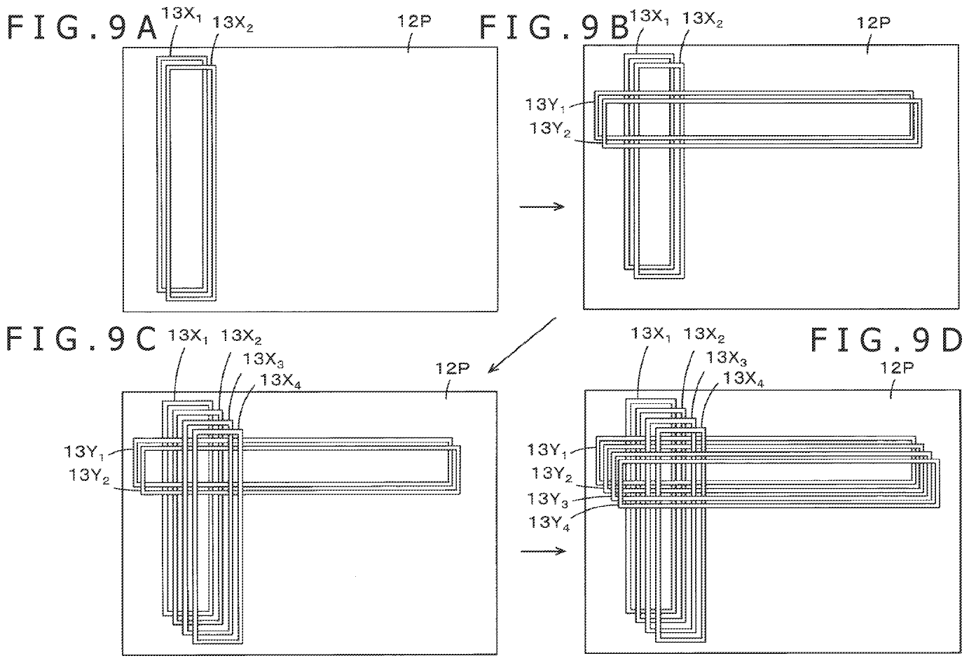

FIGS. 9A to 9D represent an example of a case where the X-axis direction loop coils 13X and the Y-axis direction loop coils 13Y are formed alternately on a two-by-two basis. Also in the case of the present example, the X-axis direction loop coils 13X are arranged in order in the X-axis direction from the left end edge side to the right end edge side in FIG. 1A of the rectangular substrate 11 while mutual overlaps of the X-axis direction loop coils 13X are tolerated, and the Y-axis direction loop coils 13Y are arranged in order in the Y-axis direction from the upper end edge side to the lower end edge side in FIG. 1A of the rectangular substrate 11 while mutual overlaps of the Y-axis direction loop coils 13Y are tolerated.

Specifically, in the example of FIGS. 9A to 9D, first, as illustrated in FIG. 9A, two X-axis direction loop coils 13X₁ and 13X₂ adjacent to each other are formed. Thereafter, as illustrated in FIG. 9B, two Y-axis direction loop coils 13Y₁ and 13Y₂ adjacent to each other are formed.

Next, as illustrated in FIG. 9C, two X-axis direction loop coils 13X₃ and 13X₄ which are adjacent to the previously formed X-axis direction loop coils 13X₁ and 13X₂ are formed. After the two X-axis direction loop coils 13X₃ and 13X₄ are formed, next, as illustrated in FIG. 9D, two Y-axis direction loop coils 13Y₃ and 13Y₄ which are adjacent to the previously formed Y-axis direction loop coils 13Y₁ and 13Y₂ are formed. Subsequently, each two X-axis direction loop coils 13X adjacent to each other and each two Y-axis direction loop coils 13Y adjacent to each other are alternately formed in order.

Incidentally, each three or more X-axis direction loop coils 13X and each three or more Y-axis direction loop coils 13Y may be formed alternately instead of alternately forming each two X-axis direction loop coils 13X and each two Y-axis direction loop coils 13Y.

In addition, in the case where each plurality of X-axis direction loop coils 13X and each plurality of Y-axis direction loop coils 13Y are formed alternately, each identical number of X-axis direction loop coils 13X and each identical number of Y-axis direction loop coils 13Y are formed in the above-described example. However, each different number of X-axis direction loop coils 13X and each different number of Y-axis direction loop coils 13Y may be formed. In that case, the different numbers of the X-axis direction loop coils 13X and the Y-axis direction loop coils 13Y may be set in consideration of the number of X-axis direction loop coils 13X and the number of Y-axis direction loop coils 13Y.

In addition, as for the number of X-axis direction loop coils 13X formed alternately with the Y-axis direction loop coils in the X-axis direction loop coil group formed by a plurality of X-axis direction loop coils 13X, a state in which a different number of X-axis direction loop coils 13X are formed may be mixed instead of setting all of the X-axis direction loop coils 13X to each identical number, such as each one X-axis direction loop coil 13X or each two X-axis direction loop coils 13X. The same is true in the Y-axis direction loop coil group formed by a plurality of Y-axis direction loop coils 13Y. Specifically, each two X-axis direction loop coils and each two Y-axis direction loop coils, for example, are formed alternately, and each one X-axis direction loop coil and each one Y-axis direction loop coil may be formed alternately from a midpoint. In this case, needless to say, the changed number and the position where the number is to be changed or the like can be determined for the X-axis direction loop coils and the Y-axis direction loop coils independently of each other.

### Other Embodiments or Modifications

In the foregoing embodiment, the external shape of the position detecting sensor is a rectangular shape. However, the external shape is not limited to a rectangular shape, and may be any shape. In addition, while the substrate has a planar shape, the substrate may have a curved surface shape. In addition, it is needless to say that the pattern shape of the loop coils is not limited to the rectangular shape of the foregoing embodiment.

In addition, in the foregoing embodiment, the terminal section is formed at one position of an end portion at one side of the rectangular substrate. However, the terminal section may be formed at a plurality of positions of an end portion at one side, or may be formed at end portions at a plurality of sides of the rectangular substrate. Incidentally, in the above-described position detecting sensor manufacturing method, the preprocessing unit 110 peels off the insulative coating of the wire 18 and exposes the internal conductor before the wiring unit 120 forms the sensor pattern section by the coated conductor. However, it is not essential to peel off the insulative coating of the wire 18 before performing the processing of forming the sensor pattern section. For example, after the sensor pattern section 13 is formed, the processing of peeling off the insulative coating of the wire 18 at end portions of the plurality of electrode conductor patterns of the sensor pattern section 13 may be performed.

It is to be noted that the embodiments of the present disclosure is not limited to the foregoing embodiments, and that various changes can be made without departing from the spirit of the present disclosure.

What is claimed is:

1. A position detecting sensor, comprising:
a substrate; and
a sensor pattern section adhered to one surface of the substrate by an adhesive,
the sensor pattern section having a plurality of electrode conductors each formed in a predetermined conductor pattern, the plurality of electrode conductors being made of a wire formed by insulatively coating a conductor;
the sensor pattern section including a first loop coil group formed by a plurality of first loop coils arranged in a first direction at first predetermined intervals, the first loop coils being formed by the wire and wound a predetermined number of times, and a second loop coil group formed by a plurality of second loop coils arranged at second predetermined intervals in a second direction orthogonal to the first direction;
each of a plurality of first groups of one or more of the first loop coils of the first loop coil group and each of a plurality of second groups of one or more of the second loop coils of the second loop coil group being arranged in an alternately superposed manner, and being adhered to the substrate by the adhesive.

2. The position detecting sensor according to claim 1, wherein
each of the first groups of one or more of the first loop coils of the first loop coil group includes one of the first loop coils of the first loop coil group and each of the second groups of one or more of the second loop coils of the second loop coil group includes one of the second loop coils of the second loop coil group.

3. The position detecting sensor according to claim 1, wherein
each of the first groups includes at least two of the first loop coils adjacent to each other in the first loop coil group and each of the second groups includes at least two of the second loop coils adjacent to each other in the second loop coil group.

4. The position detecting sensor according to claim 1, wherein,
a number of the one or more of the first loop coils of the first loop coil group included in each of the first groups is equal to a number of the one or more of the second loop coils of the second loop coil group included in each of the second groups.

5. The position detecting sensor according to claim 1, wherein
a number of the one or more of the first loop coils of the first loop coil group included in each of the first groups is different from a number of the one or more of the second loop coils of the second loop coil group included in each of the second groups.

6. The position detecting sensor according to claim 1, wherein
the first loop coils of the first loop coil group and the second loop coils of the second loop coil group are each arranged in a state of mutual overlap.

7. The position detecting sensor according to claim 6, wherein
the first groups of the one or more first loop coils of the first loop coils of the first loop coil group are arranged in a sequentially superposed manner from a first end of the sensor pattern section to a second end of the sensor pattern section in the first direction, and
the second groups of one or more of the second loop coils of the second loop coil group are arranged in a sequentially superposed manner from a first end of the sensor pattern section to a second end of the sensor pattern section in the second direction.

8. The position detecting sensor according to claim 1, wherein
the sensor pattern section is covered by a protective sheet adhered to the sensor pattern section via an adhesive.

9. A manufacturing method for a position detecting sensor formed by adhering a sensor pattern section to one surface of a substrate by an adhesive, the sensor pattern section including a first loop coil group formed by a plurality of first loop coils arranged at first predetermined intervals in a first direction, the first loop coils being formed by a wire being wound a predetermined number of times, the wire being formed by insulatively coating a conductor, and a second loop coil group formed by a plurality of second loop coils arranged at second predetermined intervals in a second direction orthogonal to the first direction, the manufacturing method comprising:
first forming one or more of the first loop coils within the first loop coil group;
second forming one or more of the second loop coils within the second loop coil group;
third forming the sensor pattern section by alternately repeating the first forming and the second forming; and
adhering the sensor pattern section to the substrate by pressing one side of the substrate against the sensor pattern section formed by the third forming, via the adhesive.

10. The manufacturing method for the position detecting sensor according to claim 9, wherein,
in the first forming and the second forming, the loop coils are formed using guide pins by the wire being wound a predetermined number of times on a pin attachment plate on which the guide pins are arranged, and,
in the adhering, the substrate to which the sensor pattern section is adhered is separated from the pin attachment plate after the sensor pattern section is adhered to the substrate.

11. The manufacturing method for the position detecting sensor according to claim 10, further comprising:
bonding a protective sheet to a side of the sensor pattern section, the side being opposite to the substrate side, before or after the adhering.
